(19) United States
(12) Patent Application Publication
(10) Pub. No.: US 2025/0338476 A1
(43) Pub. Date: Oct. 30, 2025

(54) SEMICONDUCTOR DEVICE AND METHOD OF FORMING THE SAME

(71) Applicant: YANGTZE MEMORY TECHNOLOGIES CO., LTD., Wuhan (CN)

(72) Inventors: Zongliang Huo, Wuhan (CN); Wei Xu, Wuhan (CN); Chao Sun, Wuhan (CN); Wenjie Chen, Wuhan (CN); Beibei Li, Wuhan (CN)

(21) Appl. No.: 18/671,420

(22) Filed: May 22, 2024

(30) Foreign Application Priority Data
Apr. 28, 2024 (CN) 202410525368.3

(51) Int. Cl. H10B 12/00

(52) U.S. Cl. CPC H10B 12/315; H10B 12/05

(57) ABSTRACT

A semiconductor device includes a first channel structure extending in a first direction in a stack structure, a conductive layer extending in a second direction perpendicular to the first direction and surrounding at least partial of the first channel structure, a first isolation structure extending in the first direction and the second direction, and a second isolation structure extending in the first direction and the second direction. The first channel structure and the conductive layer are disposed between the first isolation structure and the second isolation structure, and a first distance between the first channel structure and the first isolation structure is less than a second distance between the first channel structure and the second isolation structure.

### CROSS-REFERENCE TO RELATED APPLICATIONS

This application claims the benefit of priority to Chinese Application No. 202410525368.3, filed on Apr. 28, 2024, which is incorporated herein by reference in its entirety.

### BACKGROUND

The present disclosure relates to semiconductor technology, and more particularly, to semiconductor devices and the method of forming the semiconductor devices.

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a semiconductor device is disclosed. The semiconductor device includes a first channel structure extending in a first direction in a stack structure, a conductive layer extending in a second direction perpendicular to the first direction and surrounding at least partial of the first channel structure, a first isolation structure extending in the first direction and the second direction, and a second isolation structure extending in the first direction and the second direction. The first channel structure and the conductive layer are disposed between the first isolation structure and the second isolation structure, and a first distance between the first channel structure and the first isolation structure is less than a second distance between the first channel structure and the second isolation structure.

In some implementations, the semiconductor device further includes a capacitor structure. An electrode of the capacitor structure is coupled to the first channel structure.

In some implementations, the first channel structure includes a semiconductor core extending in the first direction in the stack structure, and a gate dielectric layer at least partially surrounding the semiconductor core and extending in the first direction in the stack structure.

In some implementations, the gate dielectric layer is in contact with the first isolation structure.

In some implementations, the semiconductor core includes indium gallium zinc oxide (IGZO).

In some implementations, the first channel structure includes a semiconductor core extending in the first direction in the stack structure, a first gate dielectric layer at least partially surrounding a first portion of the semiconductor core, a second gate dielectric layer at least partially surrounding a second portion of the semiconductor core, a first conductive layer at least partially surrounding the first gate dielectric layer, and a second conductive layer at least partially surrounding the second gate dielectric layer. The first gate dielectric layer is separated from the second gate dielectric layer by a third portion of the semiconductor core between the first portion and the second portion. The first conductive layer is separated from the second conductive layer by a dielectric layer.

In some implementations, the semiconductor device further includes a second channel structure disposed between the first isolation structure and the second isolation structure. A third distance between the second channel structure and the first isolation structure is greater than a fourth distance between the second channel structure and the second isolation structure.

In some implementations, the semiconductor device further includes a dielectric structure extending in the first direction and surrounded by the conductive layer.

In some implementations, each of the first isolation structure and the second isolation structure comprises a dielectric wall straightly extending in the second direction.

In some implementations, each of the first isolation structure and the second isolation structure comprises a dielectric wall wavily extending in the second direction.

In some implementations, a cross-section of the first channel structure in a lateral plane is a round shape or an oval shape.

In another aspect, a semiconductor device is disclosed. The semiconductor device includes a first channel structure extending in a first direction in a stack structure, a second channel structure extending in the first direction in the stack structure, a conductive layer extending in a second direction perpendicular to the first direction and surrounding at least partial of the first channel structure and the second channel structure, a first isolation structure extending in the first direction and the second direction, and a second isolation structure extending in the first direction and the second direction. The first channel structure, the second channel structure, and the conductive layer are disposed between the first isolation structure and the second isolation structure. The first channel structure and the second channel structure are unaligned in the second direction. A first distance between the first channel structure and the first isolation structure is less than a second distance between the first channel structure and the second isolation structure. A third distance between the second channel structure and the first isolation structure is greater than a fourth distance between the second channel structure and the second isolation structure.

In some implementations, the first channel structure includes a semiconductor core extending in the first direction in the stack structure, and a gate dielectric layer at least partially surrounding the semiconductor core and extending in the first direction in the stack structure.

In some implementations, the first channel structure includes a semiconductor core extending in the first direction in the stack structure, a first gate dielectric layer at least partially surrounding a first portion of the semiconductor core, and a second gate dielectric layer at least partially surrounding a second portion of the semiconductor core. The first gate dielectric layer is separated from the second gate dielectric layer by a third portion of the semiconductor core between the first portion and the second portion. The semiconductor core is formed by an epitaxial growth operation on bit lines.

In a further aspect, a method of forming a semiconductor device is disclosed. The method includes forming a stack structure comprising an array of channel structures extending in a first direction and a conductive layer at least partially surrounding the array of channel structures, forming a first opening and a second opening in the stack structure extending in the first direction and a second direction perpendicular to the first direction, and forming a first isolation structure in the first opening and a second isolation structure in the second opening. A first distance between a center of the channel structure and the first isolation structure is less than a second distance between the center of the channel structure and the second isolation structure.

In some implementations, the bit lines are formed extending in the second direction. A first dielectric layer is formed on the bit lines. A first sacrificial layer is formed on the first dielectric layer. An array of channel holes is formed extending through the first dielectric layer and the first sacrificial layer to expose the bit lines. The array of channel structures is formed in the array of channel holes. The conductive layer is formed surrounding the array of channel structures.

In some implementations, an epitaxial growth operation is performed on the bit lines to form an array of semiconductor pillars in the array of channel holes. The first sacrificial layer is removed to form a first trench. The exposed portion of the sidewalls of the semiconductor pillars is oxidized.

In some implementations, a conductive material is filled in the first trench to form the conductive layer.

In some implementations, a dielectric material is filled in the first opening and the second opening.

In some implementations, the bit lines are formed extending in the second direction. A first dielectric layer is formed on the bit lines. The conductive layer is formed on the first dielectric layer. An array of channel holes is formed extending through the first dielectric layer and the conductive layer to expose the bit lines. An epitaxial growth operation is performed on the bit lines to form the array of channel structures in the array of channel holes.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1 illustrates a schematic circuit diagram of an exemplary memory device, according to some implementations of the present disclosure.

FIG. 2 illustrates a schematic plan view of an exemplary memory device, according to some implementations of the present disclosure.

FIG. 3 illustrates a cross-sectional view of an exemplary memory device, according to some implementations of the present disclosure.

FIG. 4 illustrates a schematic plan view of another exemplary memory device, according to some implementations of the present disclosure.

FIG. 5 illustrates a schematic plan view of another exemplary memory device, according to some implementations of the present disclosure.

FIG. 6 illustrates a schematic plan view of another exemplary memory device, according to some implementations of the present disclosure.

FIGS. 7A-7B illustrate schematic plan views of another exemplary memory device, according to some implementations of the present disclosure.

FIG. 8 illustrates a cross-sectional view of another exemplary memory device, according to some implementations of the present disclosure.

FIGS. 9-14 illustrate cross-sectional views of the memory device shown in FIG. 3 at various stages of a fabrication process, according to some aspects of the present disclosure.

FIG. 15 illustrates a flowchart of a method for forming a memory device, according to some aspects of the present disclosure.

FIGS. 16-21 illustrate cross-sectional views of the memory device shown in FIG. 8 at various stages of a fabrication process, according to some aspects of the present disclosure.

FIG. 22 illustrates a block diagram of a system having a memory device, according to some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means perpendicular to the lateral surface of a substrate.

Transistors are used as the switch or selecting devices in the memory cells of some memory devices, such as dynamic radon access memory (DRAM). In a one-transistor-one-capacitor (1T1C) DRAM structure, the data are stored in the capacitors. In the vertical gate DRAM process technology route, there are two architectural directions. One architectural direction is a single metal gate (SMG), which saves area, but has poor gate control and high process difficulty. The other architectural direction is gate all around (GAA), which can directly or epitaxially form the channel and has better channel holes. Both existing architectural designs have a problem of difficulty in shrinking the sizes.

To address the aforementioned issues, the present disclosure introduces a solution in which new word line structures and control methods are proposed to avoid the problem of difficulty in shrinking thereby breaking the current density limit. Consistent with the scope of the present disclosure, according to some implementations of the present disclosure, vertical GAA structure and double-layer or multi-layer word lines with staggered isolation structures are used in the disclosed memory devices. Specifically, the word line gates can be formed by using an alternative dielectric stack and a subsequent gate replacement process, and the channel structures can be formed by using epitaxial growth to realize the channel. Furthermore, the channel structures are asymmetrically placed between two word line cut structures, and the word line high resistance and/or the open issues can be therefore avoided.

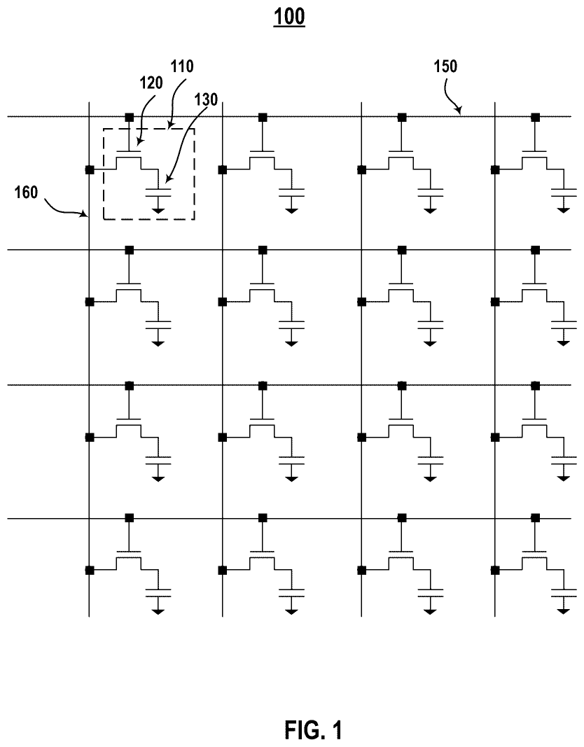

FIG. 1 illustrates a schematic circuit diagram of a memory device 100, according to some implementations of the present disclosure. Memory device 100 may include a memory cell array in which each memory cell 110 includes a vertical transistor 120 and a storage unit coupled to vertical transistor 120. In some implementations, as shown in FIG. 1, the memory cell array is a DRAM cell array, and the storage unit is a capacitor 130 for storing charge as the binary information stored by the respective DRAM cell. In some other implementations not shown in the figures, the memory cell array is a phase-change material (PCM) cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 may be arranged in a two-dimensional (2D) array having rows and columns. Memory device 100 may include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground.

Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

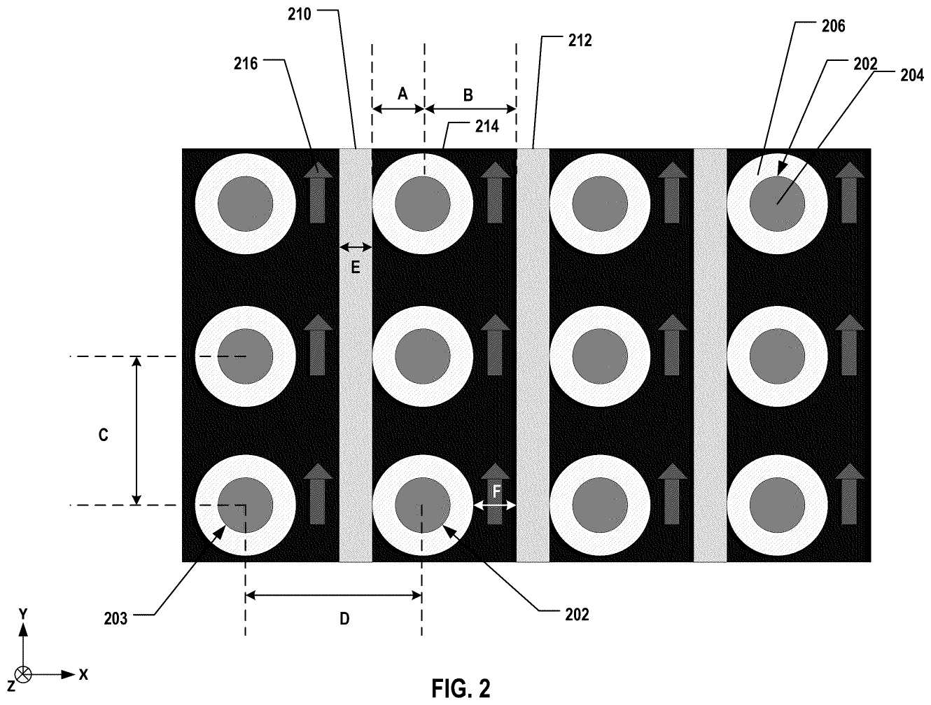

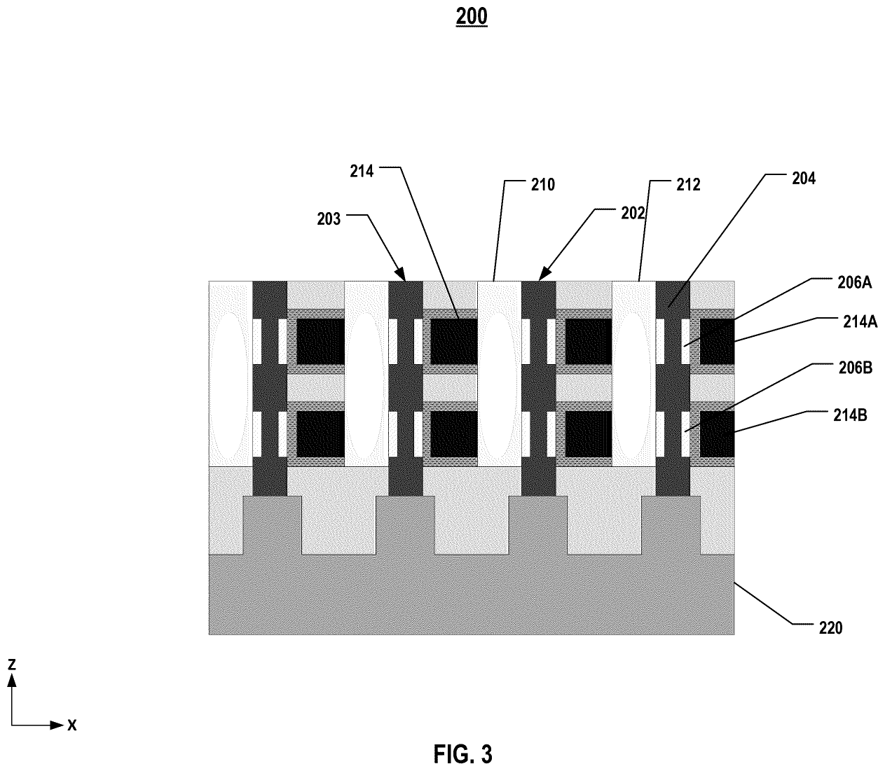

FIG. 2 illustrates a schematic plan view of a memory device 200, according to some implementations of the present disclosure. FIG. 3 illustrates a cross-sectional view of memory device 200, according to some implementations of the present disclosure. As shown in FIG. 2 and FIG. 3, memory device 200 includes a first channel structure 202 and a second channel structure 203. First channel structure 202 and second channel structure 203 both extend in a first direction, e.g., the Z-direction, in a stack structure. In some implementations, first channel structure 202 and second channel structure 203 are the vertical transistors extending in the Z-direction. Memory device 200 further includes a conductive layer 214 extending in a second direction, e.g., the Y-direction, perpendicular to the first direction and surrounding at least partial of first channel structure 202 and second channel structure 203. In some implementations, conductive layer 214 is the word lines extending in the Y-direction. Memory device 200 further includes a first isolation structure 210 and a second isolation structure 212, and first isolation structure 210 and second isolation structure 212 both extend in the Y-direction and the Z-direction. In some implementations, first isolation structure 210 and second isolation structure 212 are the word line cut structure to separate the word lines. Memory device 200 further includes bit lines 220 extending in the X-direction. In some implementations, each of first channel structure 202 and second channel structure 203 may include a semiconductor core 204, or called semiconductor pillar, and a gate dielectric layer 206 between the semiconductor core 204 and the stack structure to insulating the semiconductor core 204 from the conductive layer 214. The arrow 216 in FIG. 2 illustrates the current flow direction in conductive layer 214 (the word lines).

As shown in FIG. 2, first channel structure 202 and conductive layer 214 are disposed between first isolation structure 210 and second isolation structure 212, and a first distance A between first channel structure 202 and first isolation structure 210 is less than a second distance B between first channel structure 202 and second isolation structure 212. In some implementations, memory device 200 further includes a capacitor structure, e.g., capacitor 130, and an electrode of the capacitor structure is coupled to the first channel structure.

As shown in FIG. 2 and FIG. 3, first channel structure includes a semiconductor core 204 extending in the Z-direction in the stack structure, and a gate dielectric layer 206 at least partially surrounding semiconductor core 204 and extending in the Z-direction in the stack structure. In some implementations, semiconductor core 204 with the surrounding conductive layer 214 can form the gate-all-around (GAA) type vertical transistors stacked in the vertical direction (the Z-direction). In some implementations, the material of semiconductor core 204 can be polysilicon. In some other implementations, a material of semiconductor core 204 can be a metal oxide semiconductor material, such as indium gallium zinc oxide (IGZO). It is understood that the plan view of semiconductor core 204 in FIG. 2 may have any suitable shape, such as a square shape, a rectangular shape (or a trapezoidal shape), a circular shape, a partial circular shape, an oval shape, a partial oval shape, or any other suitable shapes. Bit line 220 can be connected to one end (e.g., the lower end) of semiconductor core 204, and the capacitor can be connected to the other end of semiconductor core 204. In some implementations, gate dielectric layer 206 is located between semiconductor core 204 and conductive layer 214. Gate dielectric layer 206 can include any suitable dielectric materials, such as silicon oxide, silicon nitride, silicon oxynitride, or high-k dielectrics. For example, gate dielectric layer 206 may include silicon oxide, i.e., gate oxide. As shown in FIG. 2 and FIG. 3, in some implementations, gate dielectric layer 206 is in contact with first isolation structure 210.

In some implementations, first channel structure 202 may include more than one gate dielectric layer 206. For example, as shown in FIG. 3, semiconductor core 204 extending in the Z-direction in the stack structure may be at least partially surrounded by a first gate dielectric layer 206A and a second gate dielectric layer 206B. In some implementations, a first conductive layer 214A at least partially surrounds first gate dielectric layer 206A, and a second conductive layer 214B at least partially surrounds second gate dielectric layer 206B. First gate dielectric layer 206A is separated from second gate dielectric layer 206B by a portion of semiconductor core 204. First conductive layer 214A is separated from second conductive layer 214B by a dielectric layer.

As shown in FIG. 2, in some implementations, the distance C between two first channel structures 202 in the Y-direction may be between 20 nm and 60 nm. In some implementations, the distance C between two first channel structures 202 in the Y-direction may be between 35 nm and 45 nm. In some implementations, the distance C between two first channel structures 202 in the Y-direction may be 41 nm. In some implementations, the distance D between two first channel structures 202 in the X-direction may be between 20 nm and 60 nm. In some implementations, the distance D between two first channel structures 202 in the X-direction may be between 35 nm and 45 nm. In some implementations, the distance D between two first channel structures 202 in the X-direction may be 41 nm. In some implementations, the width E of first isolation structure 210 and/or second isolation structure 212 in the X-direction may be between 2 nm and 20 nm. In some implementations, the width E of first isolation structure 210 and/or second isolation structure 212 in the X-direction may be between 5 nm and 15 nm. In some implementations, the width E of first isolation structure 210 and/or second isolation structure 212 in the X-direction may be 10 nm. In some implementations, the distance F between gate dielectric layer 206 and second isolation structure 212 in the X-direction may be between 2 nm and 20 nm. In some implementations, the distance F between gate dielectric layer 206 and second isolation structure 212 in the X-direction may be between 5 nm and 15 nm. In some implementations, the distance F between gate dielectric layer 206 and second isolation structure 212 in the X-direction may be 10 nm.

Since first channel structure 202 is not located at the center between first isolation structure 210 and/or second isolation structure 212, the distance F between gate dielectric layer 206 and second isolation structure 212 in the X-direction may be shrunk to a smaller size but still achieve the requirement of the high-speed path of the current flow of the word lines. Hence, the size of memory device 200 can be effectively reduced.

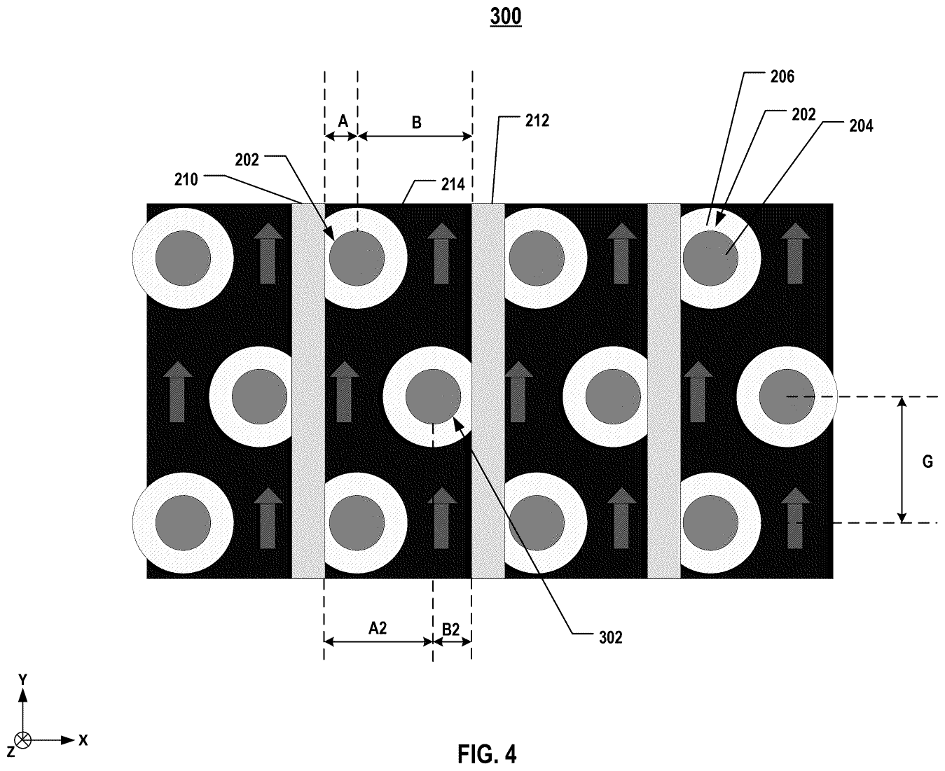

FIG. 4 illustrates a schematic plan view of another exemplary memory device 300, according to some implementations of the present disclosure. As shown in FIG. 4, memory device 300 may include first channel structure 202 and a second channel structure 302, and first channel structure 202 and second channel structure 302 are misaligned in the Y-direction. Second channel structure 302 is disposed between first isolation structure 210 and second isolation structure 212. As shown in FIG. 4, first distance A between first channel structure 202 and first isolation structure 210 is less than second distance B between first channel structure 202 and second isolation structure 212. A third distance A2 between second channel structure 302 and first isolation structure 210 is greater than a fourth distance B2 between second channel structure 302 and second isolation structure 212. In some implementations, the distance A is equal to the distance B2, and the distance B is equal to the distance A2. In some implementations, the distance G between first channel structure 202 and second channel structure 302 in the Y-direction may be between 20 nm and 60 nm. In some implementations, the distance G between first channel structure 202 and second channel structure 302 in the Y-direction may be between 30 nm and 40 nm. In some implementations, the distance G between first channel structure 202 and second channel structure 302 in the Y-direction may be 35.5 nm.

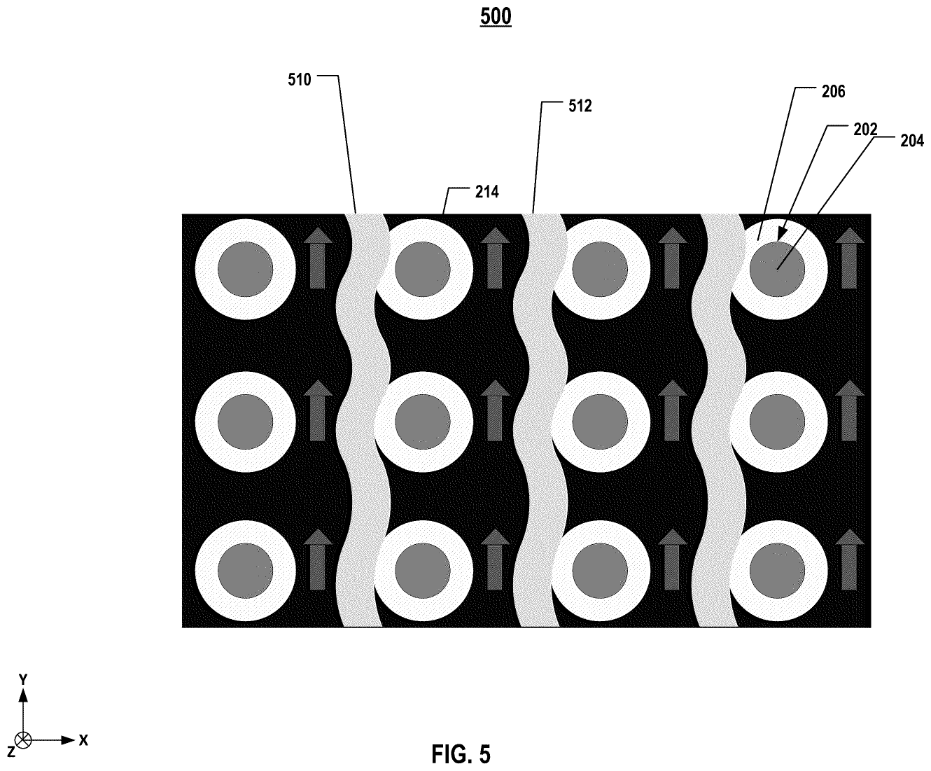

FIG. 5 illustrates a schematic plan view of another exemplary memory device 500, according to some implementations of the present disclosure. As shown in FIG. 5, memory device 500 includes a first isolation structure 510 and a second isolation structure 512. In some implementations, first isolation structure 510 and second isolation structure 512 are dielectric walls wavily extending in the Y-direction. Compared to first isolation structure 210 and second isolation structure 212 of memory device 200, which are dielectric walls straightly extending in the Y-direction, first isolation structure 510 and second isolation structure 512 of memory device 500 have a different shape. It is understood that the shape of the isolation structures, e.g., first isolation structure 210 and second isolation structure 212 of memory device 200 and or first isolation structure 510 and second isolation structure 512 of memory device 500, may have various shapes and/or sizes according to different design or layout requirements.

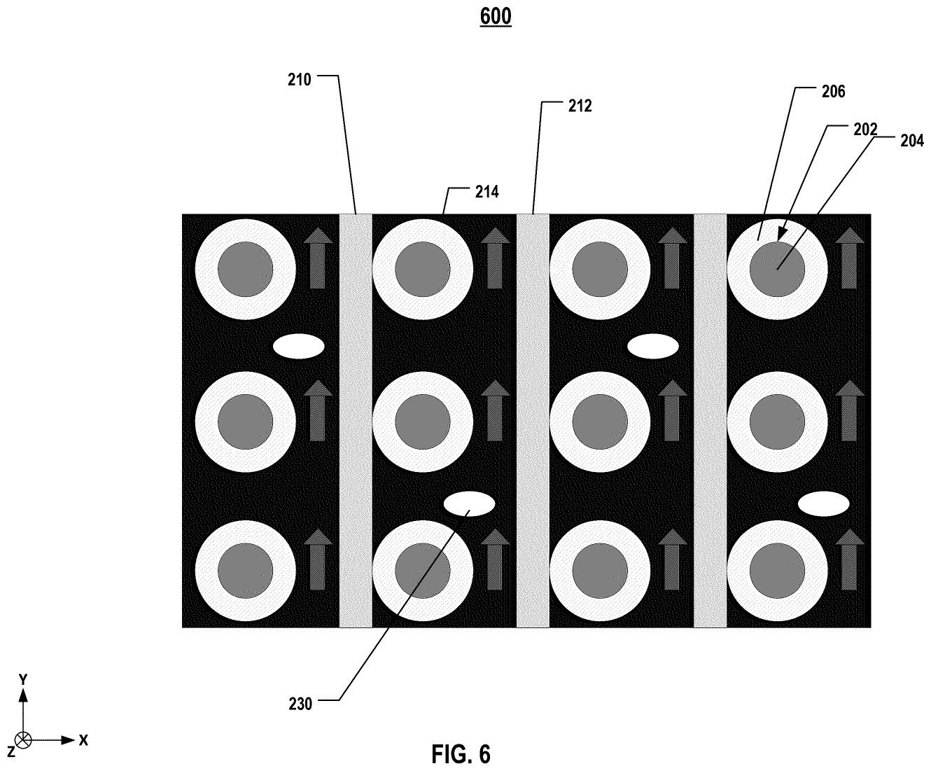

FIG. 6 illustrates a schematic plan view of another exemplary memory device 600, according to some implementations of the present disclosure. As shown in FIG. 6, memory device 600 may further include a dielectric structure 230 extending in the Z-direction and surrounded by conductive layer 214. In some implementations, for forming conductive layer 214 by performing a replacement operation to replace a dielectric material or a sacrificial material with a conductive material, an opening could be formed extending in the Z-direction through the stack structure. The dielectric material or the sacrificial material can be removed and replaced with the conductive material to form conductive layer 214 through the opening. After the replacement operation, the opening can be filled with a dielectric material to form dielectric structure 230.

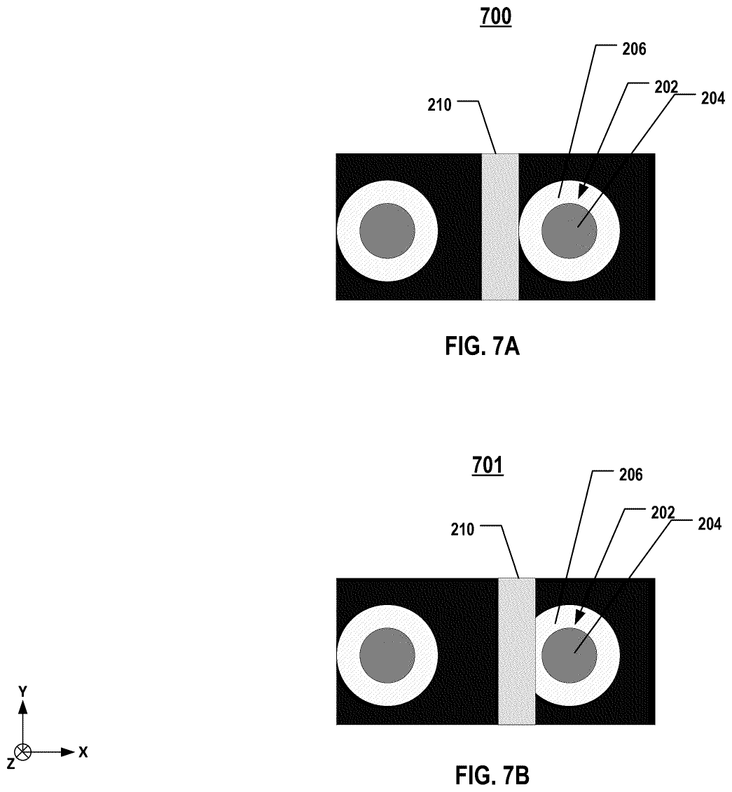

FIGS. 7A-7B illustrate schematic plan views of exemplary memory devices 700 and 701, according to some implementations of the present disclosure. As shown in FIG. 7A, in some implementations, first isolation structure 210 can be just cut gate dielectric layer 206. In some implementations, first isolation structure 210 can be separated from gate dielectric layer 206. In some implementations, as shown in FIG. 7B, first isolation structure 210 can be in contact with gate dielectric layer 206 with a large area.

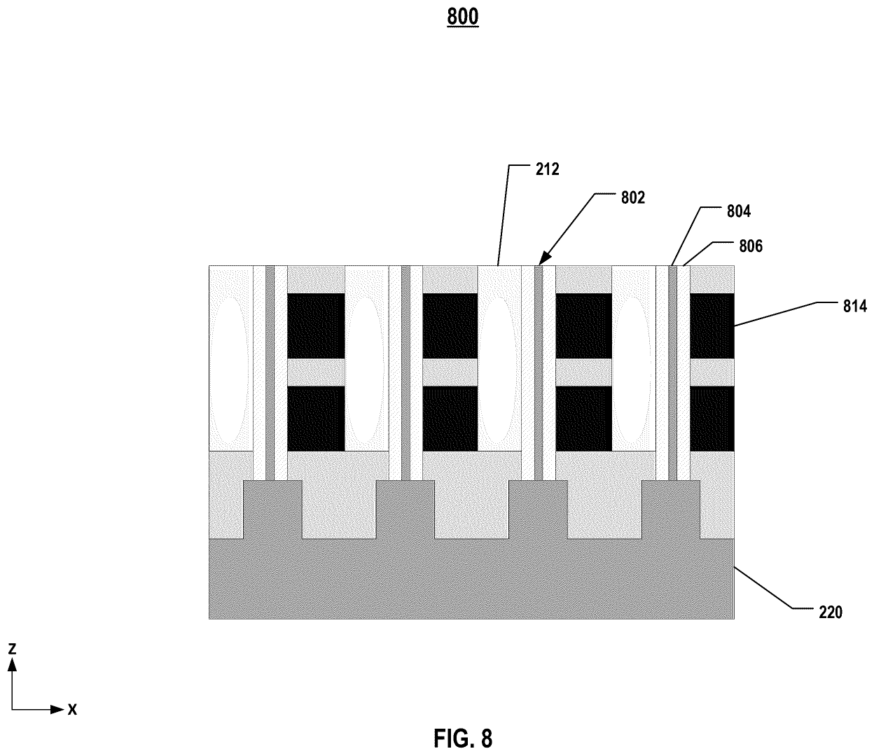

FIG. 8 illustrates a cross-sectional view of another exemplary memory device 800, according to some implementations of the present disclosure. In some implementations, memory device 800 in FIG. 8 may be similar to memory device 200. In some implementations, memory device 800 includes a first channel structure 802 includes a semiconductor core 804 extending in the Z-direction in the stack structure, and a gate dielectric layer 806 at least partially surrounding semiconductor core 804 and extending in the Z-direction in the stack structure. In some implementations, semiconductor core 804 with the surrounding conductive layer 814 can form the gate-all-around (GAA) type vertical transistors stacked in the vertical direction (the Z-direction). In some implementations, the material of semiconductor core 804 can be polysilicon. In some other implementations, a material of semiconductor core 804 can be a metal oxide semiconductor material, such as indium gallium zinc oxide (IGZO). Bit line 220 can be connected to one end (e.g., the lower end) of semiconductor core 804, and the capacitor can be connected to the other end of semiconductor core 804. In some implementations, gate dielectric layer 806 is located between semiconductor core 804 and conductive layer 814. Gate dielectric layer 806 can include any suitable dielectric materials, such as silicon oxide, silicon nitride, silicon oxynitride, or high-k dielectrics. For example, gate dielectric layer 806 may include silicon oxide, i.e., gate oxide. As shown in FIG. 8, in some implementations, gate dielectric layer 806 is in contact with first isolation structure 210.

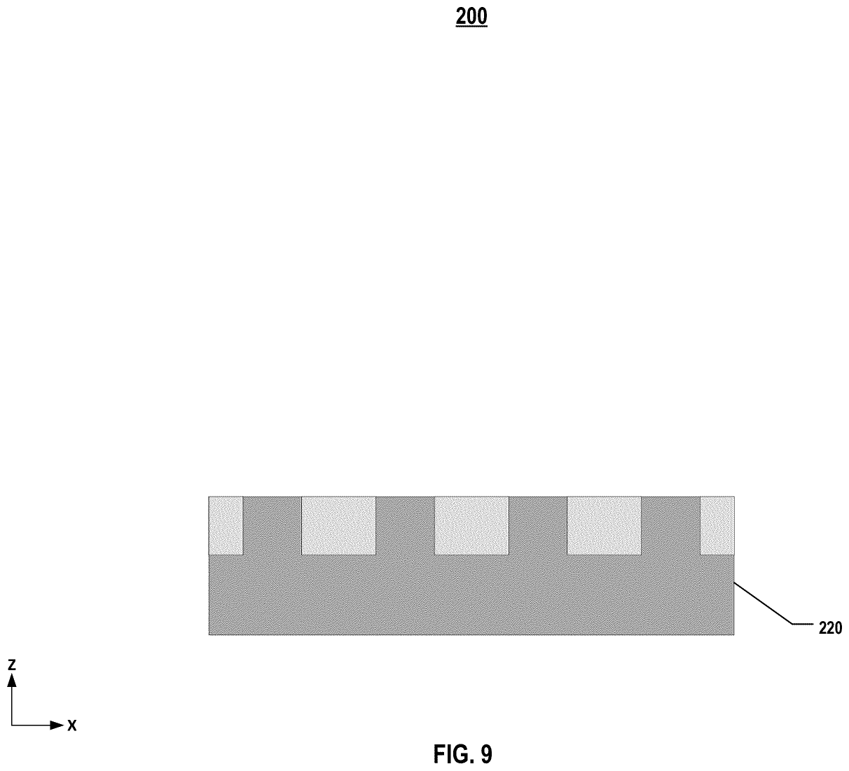

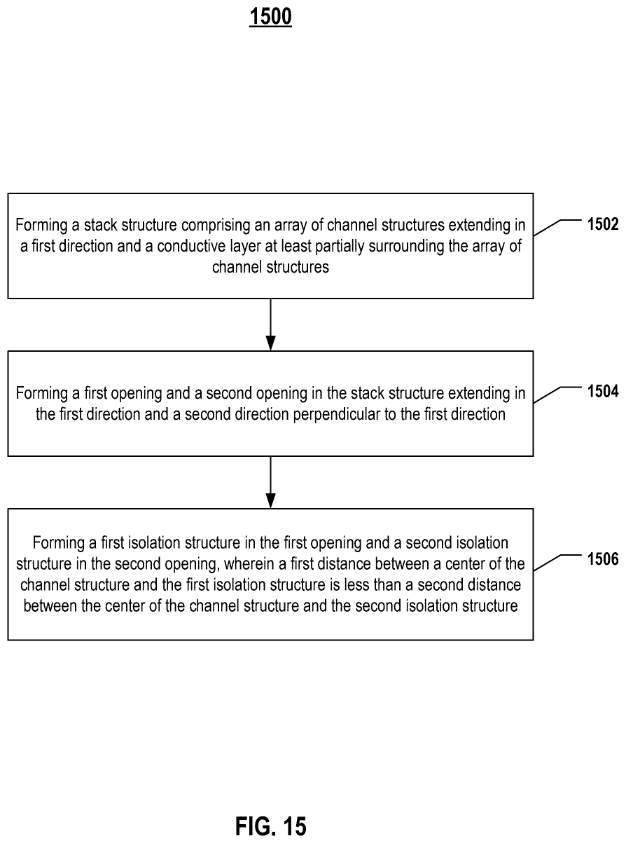

FIGS. 9-14 illustrate cross-sectional views of memory device 200 shown in FIG. 3 at various stages of a fabrication process, according to some aspects of the present disclosure. FIG. 15 illustrates a flowchart of a method 1500 for forming memory device 200, according to some aspects of the present disclosure. For the purpose of better describing the present disclosure, the memory device 200 in FIGS. 9-14 and method 1500 in FIG. 15 will be discussed together. It is understood that the operations shown in method 1500 are not exhaustive and that other operations may be performed as well before, after, or between any of the illustrated operations. Further, some of the operations may be performed simultaneously, or in a different order than shown in FIGS. 9-14 and FIG. 15.

As shown in FIGS. 9-12 and operation 1502 in FIG. 15, a stack structure including an array of channel structures extending in a first direction, e.g., the Z-direction, and a conductive layer at least partially surrounding the array of channel structures is formed. As shown in FIG. 9, bit line 220 may be formed on a substrate. In some implementations, the substrate may be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some other implementations, the substrate can be a carrier substrate, which can include any suitable semiconductor materials, or an electrically non-conductive material, such as a glass, a plastic, or a sapphire wafer. Bit line 220 may be formed on the substrate by forming a conductive layer on the substrate and performing a lithography process to pattern the conductive layer. In some implementations, bit line 220 can include any suitable conductive materials, such as polysilicon, metals (e.g., W, Cu, Al, etc.), metal compounds (e.g., TiN, TaN, etc.), or silicides. For example, bit line 220 includes multiple conductive layers, such as a W layer over a TiN layer.

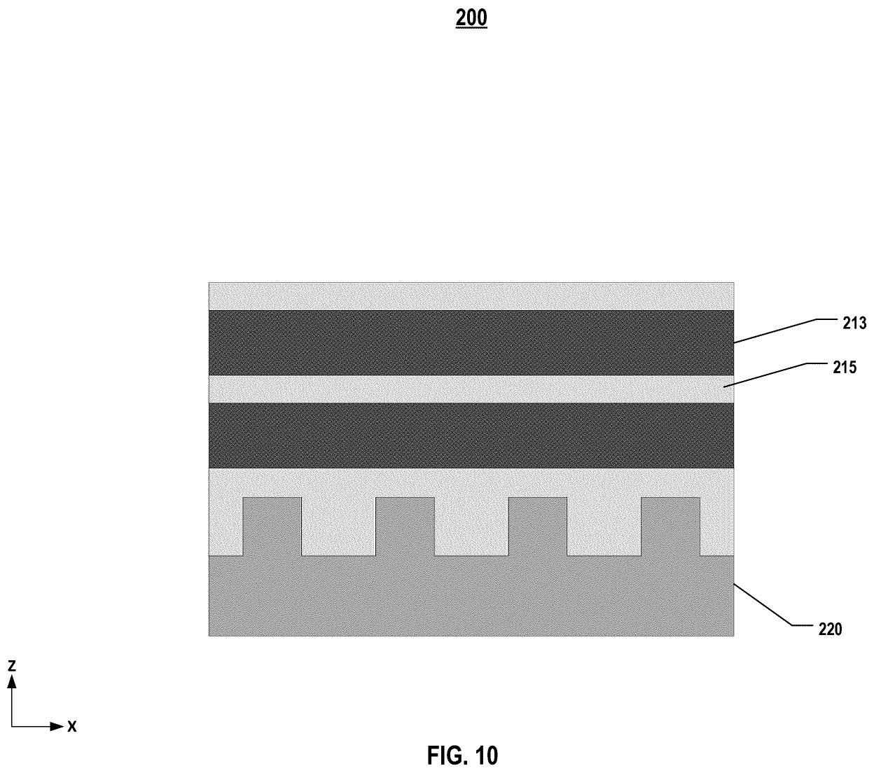

As shown in FIG. 10, a sacrificial layer 213 and a dielectric layer 215 are formed on bit line 220. In some implementations, sacrificial layer 213 can include any suitable material having an etching ratio different from that of the material of dielectric layer 215 during one or more selective etching processes. In some implementations, sacrificial layer 213 includes silicon nitride, and dielectric layer 215 includes silicon oxide. In some implementations, multiple sacrificial layers 213 and multiple dielectric layers 215 can be alternatively formed on bit line 220.

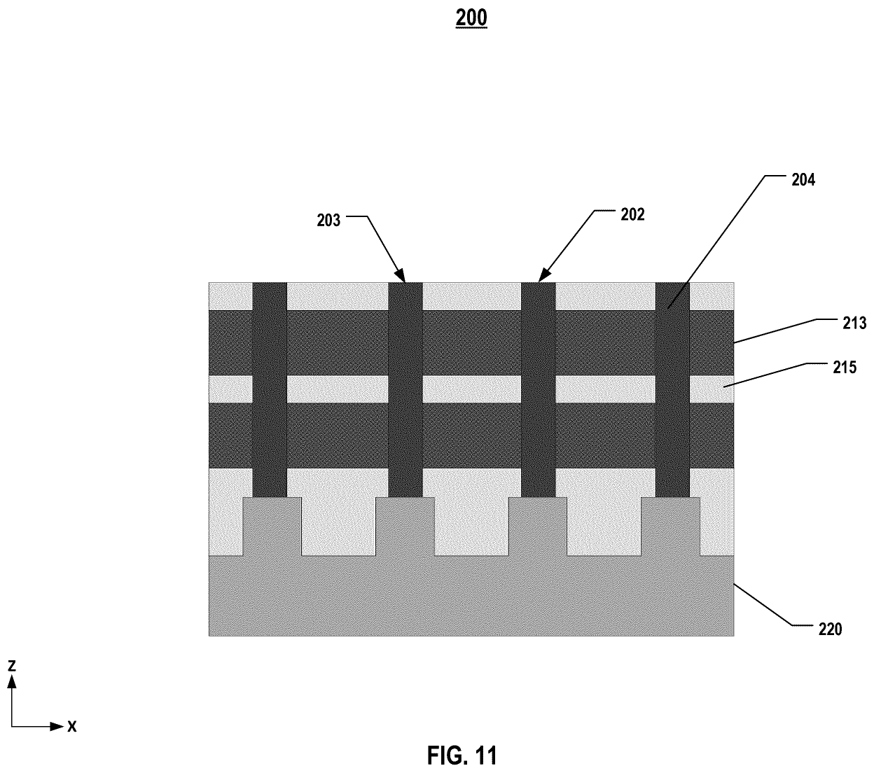

As shown in FIG. 11, an array of channel holes may be formed extending through dielectric layer 215 and sacrificial layer 213 to expose bit line 220, and an array of channel structures 202 and 203 may be formed in the array of channel holes. In some implementations, an array of channel holes (not shown) can be formed, each penetrating through sacrificial layer 213 and dielectric layer 215 to expose a corresponding bit line 220. The array of channel holes can be formed by using any suitable etching process.

As shown in FIG. 11, an array of semiconductor pillars, e.g., semiconductor core 204, can be formed in the plurality of channel holes, respectively. The lower end of semiconductor core 204 can be coupled with the corresponding bit line 220. In some implementations, the array of semiconductor core 204 can be formed by any suitable deposition process (e.g., CVD, PVD, ALD, etc.) and a followed CMP process. In some implementations, a material of semiconductor core 204 can include any suitable semiconductor material. For example, a material of semiconductor core 204 can be polysilicon. As another example, a material of semiconductor core 204 can be a metal oxide semiconductor material, such as IGZO. In some implementations, an epitaxial growth operation may be performed on bit line 220 to form an array of semiconductor pillars in the array of channel holes.

In some implementations, an opening can be formed penetrating through sacrificial layer 213 and dielectric layer 215. The opening can be formed by using any suitable etching process. Then, sacrificial layer 213 is removed from the opening to form a horizontal trench, exposing a portion of semiconductor core 204. In some implementations, a portion of the sidewalls of semiconductor core 204 is exposed. Sacrificial layer 213 can be removed by using any suitable etching process.

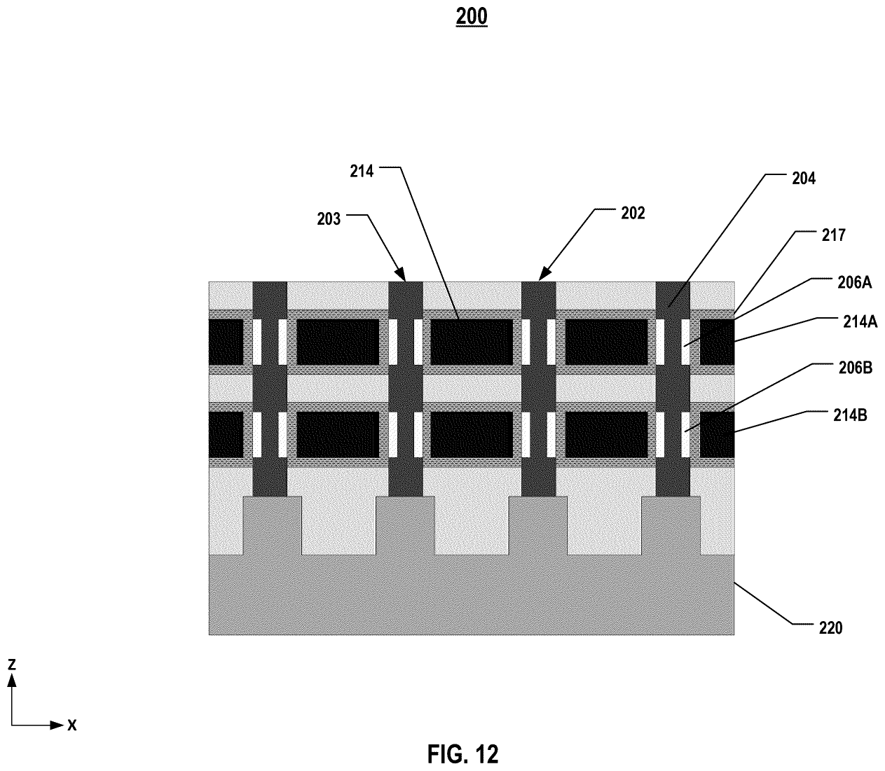

In some implementations, an oxidation operation may be performed on the exposed portion of semiconductor core 204 to form a dielectric layer. In some implementations, the oxidation operation may be performed on the exposed portion of semiconductor core 204 to form gate dielectric layer 206. Conductive layer 214 may be formed in the trench to form the word lines. In some implementations, conductive layer 214 surrounds the array of channel structures 202 and 203. In some implementations, as shown in FIG. 12, an insulating layer 217 can be formed to cover the exposed surfaces of the horizontal trench. Insulating layer 217 can include any suitable dielectric materials, such as silicon oxide, silicon nitride, silicon oxynitride, or high-k dielectrics. One or more conductive materials can be deposited on insulating layer 217 to fill the horizontal trench to form conductive layer 214. Conductive layer 214 can be used as the gate electrodes of the vertical transistors and can include any suitable conductive materials, such as polysilicon, metals (e.g., W, Cu, Al, etc.), metal compounds (e.g., TiN, TaN, etc.), or silicides. For example, conductive layer 214 may include doped polysilicon, i.e., a gate poly. In some implementations, conductive layer 214 can include multiple conductive layers, such as a W layer over a TiN layer.

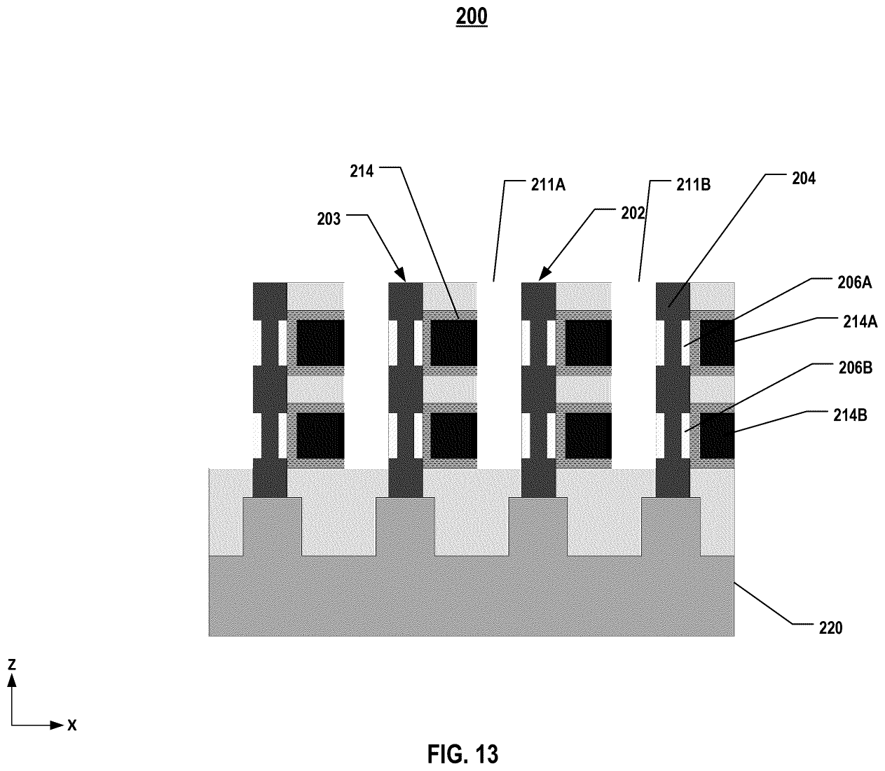

As shown in FIG. 13 and operation 1504 in FIG. 15, a first opening 211A and a second opening 211B are formed in the stack structure extending in the first direction, e.g., the Z-direction, and a second direction, e.g., the Y-direction, perpendicular to the first direction.

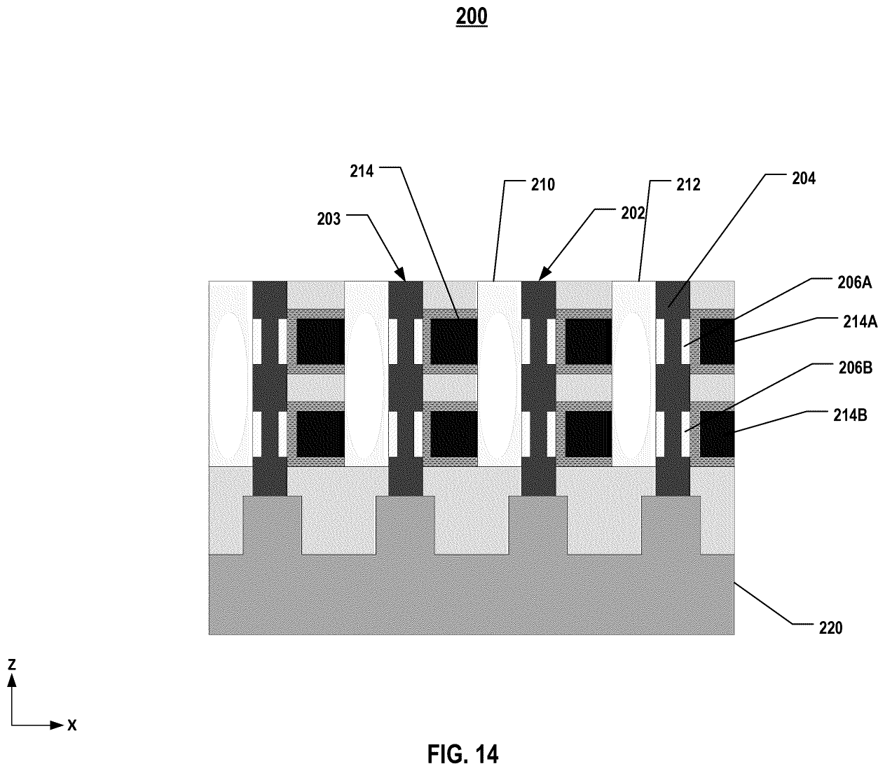

As shown in FIG. 14 and operation 1506 in FIG. 15, first isolation structure 210 is formed in first opening 211A, and second isolation structure 212 is formed in second opening 211B. In some implementations, a dielectric material is filled in first opening 211A and second opening 211B to form first isolation structure 210 and second isolation structure 212. As shown in FIG. 2, first channel structure 202 and conductive layer 214 are disposed between first isolation structure 210 and second isolation structure 212, and a first distance A between first channel structure 202 and first isolation structure 210 is less than a second distance B between first channel structure 202 and second isolation structure 212.

Since first channel structure 202 is not located at the center between first isolation structure 210 and/or second isolation structure 212, the distance F between gate dielectric layer 206 and second isolation structure 212 in the X-direction may be shrunk to a smaller size but still achieve the requirement of the high-speed path of the current flow of the word lines. Hence, the size of memory device 200 can be effectively reduced.

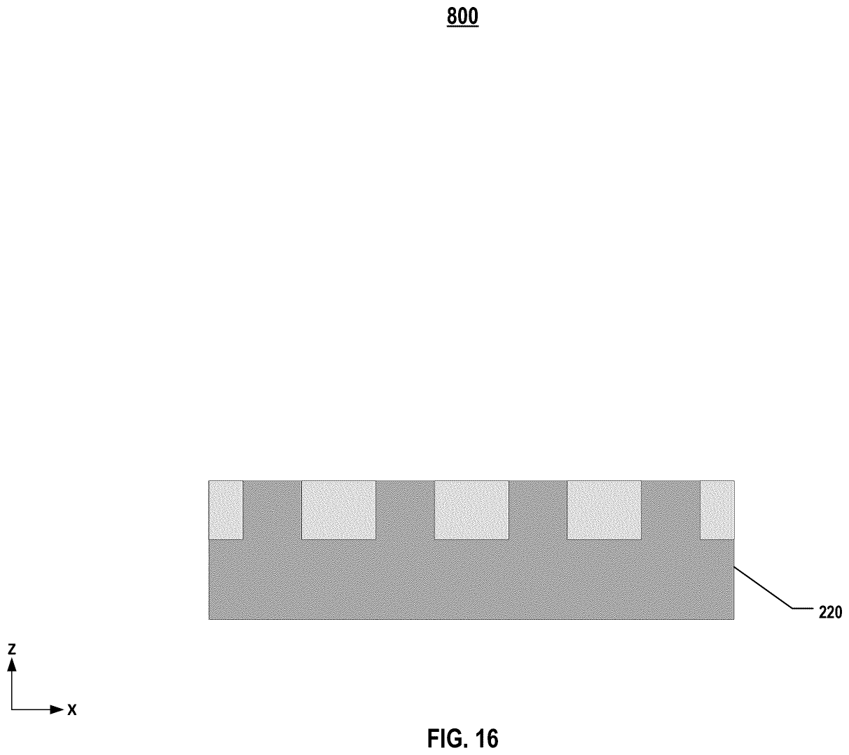

FIGS. 16-21 illustrate cross-sectional views of memory device 800 shown in FIG. 8 at various stages of a fabrication process, according to some aspects of the present disclosure. For the purpose of better describing the present disclosure, the memory device 800 in FIGS. 16-21 and method 1500 in FIG. 15 will be discussed together. It is understood that the operations shown in method 1500 are not exhaustive and that other operations may be performed as well before, after, or between any of the illustrated operations. Further, some of the operations may be performed simultaneously, or in a different order than shown in FIGS. 16-21 and FIG. 15.

As shown in FIGS. 16-19 and operation 1502 in FIG. 15, a stack structure including an array of channel structures extending in a first direction, e.g., the Z-direction, and a conductive layer at least partially surrounding the array of channel structures is formed. As shown in FIG. 16, bit line 220 may be formed on a substrate. In some implementations, the substrate may be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some other implementations, the substrate can be a carrier substrate, which can include any suitable semiconductor materials, or an electrically non-conductive material, such as a glass, a plastic, or a sapphire wafer. Bit line 220 may be formed on the substrate by forming a conductive layer on the substrate and performing a lithography process to pattern the conductive layer. In some implementations, bit line 220 can include any suitable conductive materials, such as polysilicon, metals (e.g., W, Cu, Al, etc.), metal compounds (e.g., TiN, TaN, etc.), or silicides. For example, bit line 220 includes multiple conductive layers, such as a W layer over a TiN layer.

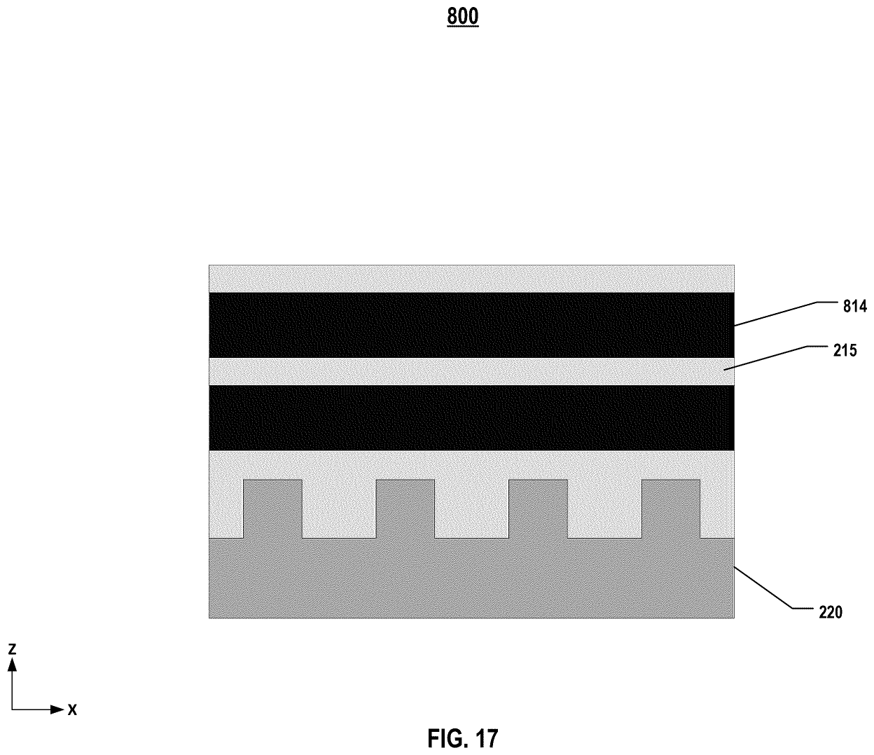

As shown in FIG. 17, a dielectric layer 215 and a conductive layer 814 are formed on bit line 220. In some implementations, dielectric layer 215 includes silicon oxide. In some implementations, conductive layer 814 can be used as the gate electrodes of the vertical transistors and can include any suitable conductive materials, such as polysilicon, metals (e.g., W, Cu, Al, etc.), metal compounds (e.g., TiN, TaN, etc.), or silicides. For example, conductive layer 814 may include doped polysilicon, i.e., a gate poly. In some implementations, conductive layer 814 can include multiple conductive layers, such as a W layer over a TiN layer. In some implementations, multiple conductive layers 814 and multiple dielectric layers 215 can be alternatively formed on bit line 220.

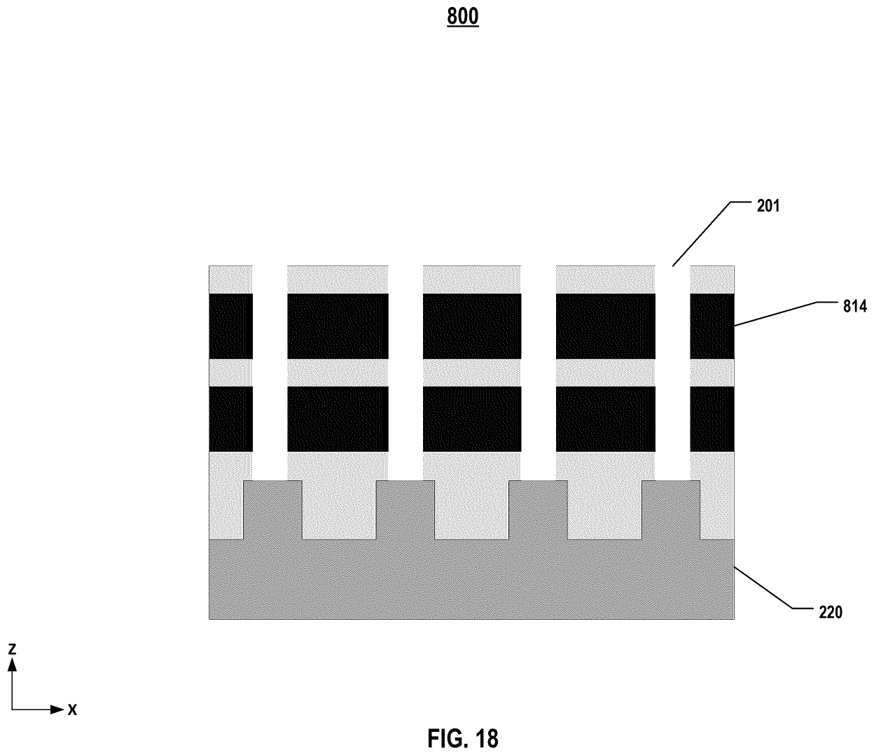

As shown in FIG. 18, an array of channel holes 201 is formed, extending through multiple conductive layers 814 and multiple dielectric layers 215 to expose bit line 220. The array of channel holes 201 can be formed by using any suitable etching process.

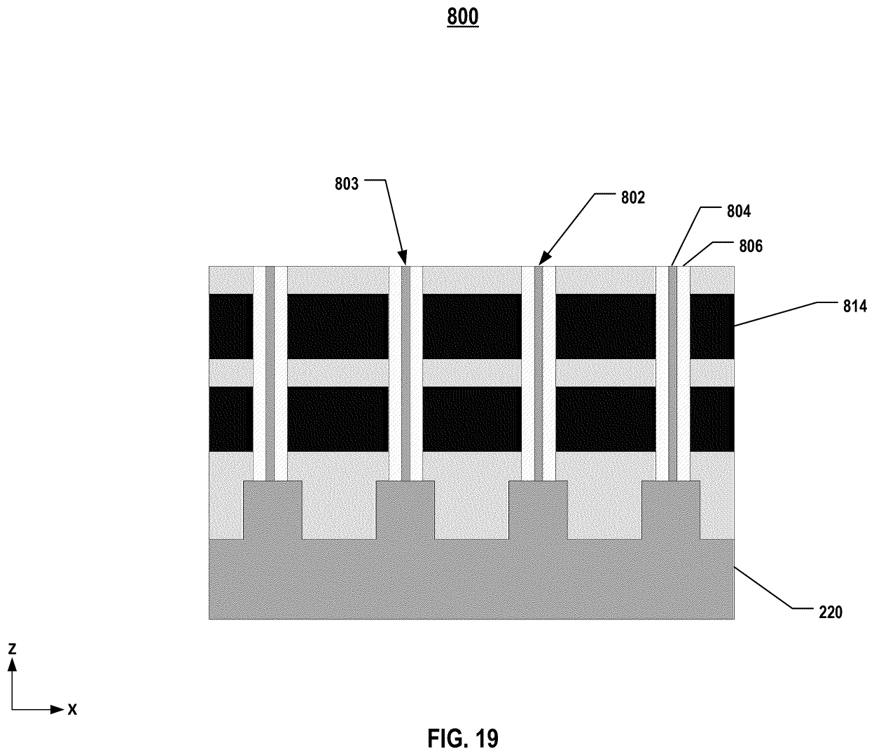

As shown in FIG. 19, an array of channel structures 802 and 803 are formed in the array of channel holes 201. In some implementations, a gate dielectric layer 806 is formed on the sidewalls of channel holes 201, and a semiconductor pillar, e.g., semiconductor core 804, is formed on gate dielectric layer 806 in channel holes 201. In some implementations, the array of gate dielectric layer 806 and semiconductor core 804 can be formed by any suitable deposition process (e.g., CVD, PVD, ALD, etc.) and a followed CMP process. In some implementations, a material of semiconductor core 804 can include any suitable semiconductor material. For example, the material of semiconductor core 804 can be polysilicon. As another example, a material of semiconductor core 804 can be a metal oxide semiconductor material, such as IGZO. In some implementations, an epitaxial growth operation may be performed on bit line 220 to form an array of semiconductor pillars in the array of channel holes 201.

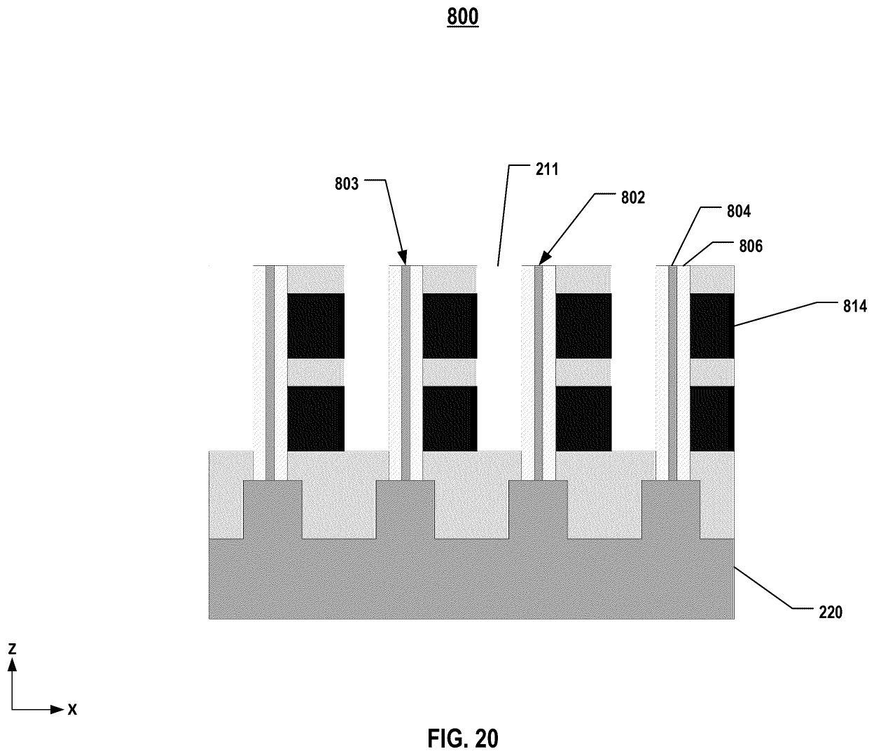

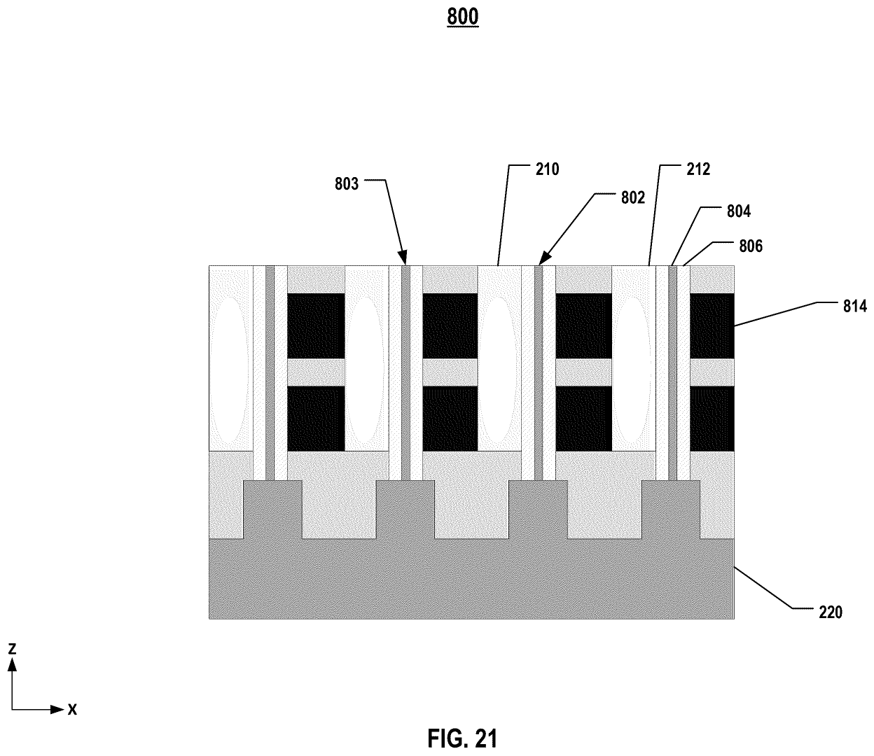

As shown in FIG. 20 and operation 1504 in FIG. 15, an opening 211 is formed in the stack structure extending in the first direction, e.g., the Z-direction, and a second direction, e.g., the Y-direction, perpendicular to the first direction. As shown in FIG. 21 and operation 1506 in FIG. 15, first isolation structure 210 and second isolation structure 212 are formed in openings 211. In some implementations, a dielectric material is filled in openings 211 to form first isolation structure 210 and second isolation structure 212.

Since first channel structure 202 is not located at the center between first isolation structure 210 and/or second isolation structure 212, the distance F between gate dielectric layer 206 and second isolation structure 212 in the X-direction may be shrunk to a smaller size but still achieve the requirement of the high-speed path of the current flow of the word lines. Hence, the size of memory device 200 can be effectively reduced.

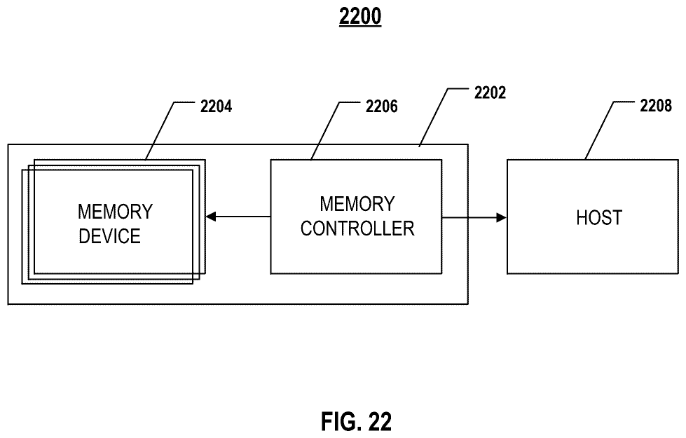

FIG. 22 illustrates a block diagram of a system 2200 having a memory device, according to some implementations of the present disclosure. System 2200 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 22, system 2200 can include a host 2208 and a memory system 2202 having one or more memory devices 2204 and a memory controller 2206. Host 2208 can be a processor of an electronic device, such as a central processing unit (CPU), or a system-on-chip (SoC), such as an application processor (AP). Host 2208 can be configured to send or receive the data to or from memory devices 2204. Memory device 2204 can be any memory devices disclosed herein, such as memory devices 200, 300, and/or 800 discussed above.

Memory controller 2206 is coupled to memory device 2204 and host 2208 and is configured to control memory device 2204, according to some implementations. Memory controller 2206 can manage the data stored in memory device 2204 and communicate with host 2208. Memory controller 2206 can be configured to control operations of memory device 2204, such as read, write, and refresh operations. Memory controller 2206 can also be configured to manage various functions with respect to the data stored or to be stored in memory device 2204 including, but not limited to refresh and timing control, command/request translation, buffer and schedule, and power management. In some implementations, memory controller 2206 is further configured to determine the maximum memory capacity that the computer system can use, the number of memory banks, memory type and speed, memory particle data depth and data width, and other important parameters. Any other suitable functions may be performed by memory controller 2206 as well. Memory controller 2206 can communicate with an external device (e.g., host 2208) according to a particular communication protocol. For example, memory controller 2206 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor device, comprising:
a first channel structure extending in a first direction in a stack structure;
a conductive layer extending in a second direction perpendicular to the first direction and surrounding at least partial of the first channel structure;
a first isolation structure extending in the first direction and the second direction; and
a second isolation structure extending in the first direction and the second direction,
wherein the first channel structure and the conductive layer are disposed between the first isolation structure and the second isolation structure, and
wherein a first distance between a center of the first channel structure and the first isolation structure is less than a second distance between the center of the first channel structure and the second isolation structure.

2. The semiconductor device of claim 1, wherein the first channel structure comprises:
a semiconductor core extending in the first direction in the stack structure; and
a gate dielectric layer laterally surrounding the semiconductor core and extending in the first direction in the stack structure.

3. The semiconductor device of claim 2, wherein the gate dielectric layer is in contact with the first isolation structure.

4. The semiconductor device of claim 2, wherein the gate dielectric layer is in contact with the conductive layer.

5. The semiconductor device of claim 2, wherein the semiconductor core comprises indium gallium zinc oxide (IGZO).

6. The semiconductor device of claim 1, wherein the first channel structure comprises:
a semiconductor core extending in the first direction in the stack structure;
a first gate dielectric layer laterally surrounding a first portion of the semiconductor core; and
a second gate dielectric layer laterally surrounding a second portion of the semiconductor core,
wherein the first gate dielectric layer is separated from the second gate dielectric layer by a third portion of the semiconductor core between the first portion and the second portion.

7. The semiconductor device of claim 6, wherein the first gate dielectric layer and the second gate dielectric layer are in contact with the first isolation structure.

8. A semiconductor device, comprising:
a first channel structure extending in a first direction in a stack structure;
a second channel structure extending in the first direction in the stack structure;
a conductive layer extending in a second direction perpendicular to the first direction and surrounding at least partial of the first channel structure and the second channel structure;
a first isolation structure extending in the first direction and the second direction; and
a second isolation structure extending in the first direction and the second direction,
wherein the first channel structure, the second channel structure, and the conductive layer are disposed between the first isolation structure and the second isolation structure, and
wherein the first channel structure and the second channel structure are unaligned in the second direction.

9. The semiconductor device of claim 8, wherein a first distance between a center of the first channel structure and the first isolation structure is less than a second distance between the center of the first channel structure and the second isolation structure.

10. The semiconductor device of claim 9, wherein a third distance between a center of the second channel structure and the first isolation structure is greater than a fourth distance between the center of the second channel structure and the second isolation structure.

11. The semiconductor device of claim 8, wherein the first channel structure comprises:
a semiconductor core extending in the first direction in the stack structure; and
a gate dielectric layer laterally surrounding the semiconductor core and extending in the first direction in the stack structure.

12. The semiconductor device of claim 11, wherein the gate dielectric layer is in contact with the first isolation structure.

13. The semiconductor device of claim 11, wherein the gate dielectric layer is in contact with the conductive layer.

14. The semiconductor device of claim 11, wherein the semiconductor core comprises indium gallium zinc oxide (IGZO).

15. The semiconductor device of claim 8, wherein the first channel structure comprises:
a semiconductor core extending in the first direction in the stack structure;
a first gate dielectric layer laterally surrounding a first portion of the semiconductor core; and
a second gate dielectric layer laterally surrounding a second portion of the semiconductor core,
wherein the first gate dielectric layer is separated from the second gate dielectric layer by a third portion of the semiconductor core between the first portion and the second portion.

16. A method of forming a semiconductor device, comprising:
forming a stack structure comprising an array of channel structures extending in a first direction and a conductive layer surrounding the array of channel structures;
forming a first opening and a second opening in the stack structure extending in the first direction and a second direction perpendicular to the first direction; and
forming a first isolation structure in the first opening and a second isolation structure in the second opening, wherein a first distance between a center of the channel structure and the first isolation structure is less than a second distance between the center of the channel structure and the second isolation structure.

17. The method of claim 16, wherein forming the stack structure comprising the array of channel structures extending in the first direction and the conductive layer surrounding the array of channel structures, comprises:
forming bit lines extending in the second direction;
forming a first dielectric layer on the bit lines;
forming a first sacrificial layer on the first dielectric layer;
forming an array of channel holes extending through the first dielectric layer and the first sacrificial layer;
forming the array of channel structures in the array of channel holes; and
forming the conductive layer surrounding the array of channel structures.

18. The method of claim 17, wherein forming the array of channel structures in the array of channel holes, comprises:
forming an array of semiconductor pillars in the array of channel holes;
removing the first sacrificial layer to form a first trench; and
oxidizing an exposed portion of sidewalls of the semiconductor pillars.

19. The method of claim 18, wherein forming the conductive layer surrounding the array of channel structures, comprises:
filling a conductive material in the first trench to form the conductive layer.

20. The method of claim 16, wherein forming the first isolation structure in the first opening and the second isolation structure in the second opening, comprises:
filing a dielectric material in the first opening and the second opening.
